(19) United States
(12) Patent Application Publication
(10) Pub. No.: US 2010/0176271 A1
(43) Pub. Date: Jul. 15, 2010

(54) PIXEL ARRAY PREVENTING THE CROSS TALK BETWEEN UNIT PIXELS AND IMAGE SENSOR USING THE PIXEL

(75) Inventors: Jae-Young Rim, Seoul (KR); Se-Jung Oh, Seoul (KR)

Correspondence Address: Jae Y. Park, Kile, Goekjian, Reed & McManus, PLLC, 1200 New Hampshire Ave. NW, Suite 570, Washington, DC, 20036, US

(73) Assignee: SILICONFILE TECHNOLOGIES INC., Seoul (KR)

(21) Appl. No.: 12/602,761

(22) PCT Filed: Jun. 17, 2008
(86) PCT No.: PCT/KR08/03400

§ 371 Date: Dec. 2, 2009

(30) Foreign Application Priority Data
Jun. 19, 2007 (KR) 10-2007-0059859

(51) Int. Cl. H01L 27/146

(52) U.S. Cl. 250/208.1; 257/E27.133

(57) ABSTRACT

The present invention provides a pixel array having a three-dimensional structure and an image sensor having the pixel array. The pixel array has a three-dimensional structure in which a photodiode, a transfer transistor, a reset transistor, a convert transistor, and a select transistor are divided and formed on a first wafer and a second wafer, chips on the first and second wafers are connected in a vertical direction after die-sorting the chips. The first wafer includes a plurality of photodiodes for generating electric charges corresponding to an incident video signal, a plurality of transfer transistors for transferring the electric charges generated by the photodiodes to floating diffusion regions, a plurality of STIs circling one of the photodiodes and one transfer transistor connected to the one photodiode, a first super-contact which extends from a lower portion of the plurality of the STIs to a lower surface of the wafer, and a second super-contact which penetrates the plurality of the STIs and a portion of the first super-contact. The electric charges accumulated in the floating diffusion regions are transferred to the second wafer through the second super-contact.

### BACKGROUND OF THE INVENTION

1. Field of the Invention

The present invention relates to a pixel array and an image sensor, and more particularly, to a pixel array having a three-dimension structure and an image sensor including the pixel array.

According to the present invention, a pixel array and an image sensor having the pixel array can satisfy various customer's requests without increasing a chip area, and high-performance products can be easily manufactured due to a high adaptability to a specific process for enhancing a dark property of the image sensor. In addition, according to the present invention, a first wafer to be formed with photodiodes and transfer transistors and a second wafer to be formed with convert transistors for converting a video signal (electric charges) detected by the transfer transistors to an electrical signal are optimally manufactured.

2. Description of the Related Art

In general, it is known that a yield of an image sensor is very low in comparison with other devices. For example, among electrical properties of the image sensor, there is dark property for reproducing an original image. In order to enhance the dark property, specific processes as well as optimized circuits are required.

If the specific process is introduced to a standard semiconductor process in order to enhance the dark property of the image sensor, the dark property of the image sensor can be enhanced. However, since the electrical property of a unit component such as a transistor becomes changed, total performances of the image sensor may be degraded. Therefore, a simple introduction of the specific process to the standard process causes a problem.

FIG. 1 is a view showing a planar structure of a conventional image sensor.

Referring to FIG. 1, the image sensor includes a pixel array having photodiodes and video signal conversion circuits for converting video signals detected by the photodiodes to electrical signals, an addressing unit for identifying positions of the photodiodes, an ADC unit for converting an analog signal to a digital signal, and an AMP unit for amplifying a small signal.

As shown in FIG. 1, in the conventional image sensor manufactured through the standard semiconductor process, a pixel array having properties of the image sensor and other function blocks (the addressing unit, the ADC unit, and the AMP unit, etc.) are formed on one wafer. Therefore, as described above, if the image sensor is manufactured through the standard process including the specific process for enhancing the dark property, the properties of components become changed, so that the yield of the image sensor is lowered.

A degree of plasma impact in etching, a presence of a sufficient heat treatment for reducing the impact, and an occurrence of various metallic contaminations during the process are considered to affect the dark property of the image sensor. In order to solve the above problems, a specific process is necessarily introduced to the standard semiconductor manufacturing process.

FIG. 2 shows a conventional image sensor having a three-dimensional structure.

Referring to FIG. 2, in the image sensor having the three-dimensional structure, a pixel array is formed on the one wafer and the remaining function blocks are formed on the other wafer. Chips manufactured on the two different wafers are subject to die-sorting, and after that, the chips are combined in a two-layer structure.

That is, a wafer to be formed with the function blocks through the standard semiconductor process and a wafer to be additionally formed with the function blocks through the specific process for enhancing the dark property are separately manufactured. Therefore, the problems caused from the conventional image sensor where all of the function blocks are formed on a single wafer can be solved.

Although not shown in FIG. 2, a plurality of unit pixels are arranged in a two-dimensional structure in the pixel array. Each unit pixel includes a unit photodiode and a unit video signal conversion circuit for converting electric charges generated by the photodiode corresponding to a video signal to an electrical signal. The photodiode generates electric charges corresponding to the video signal incident to the photodiode. As an area of the photodiode is increased, a width of change of the electric charges generated by the photodiode corresponding to the incident video signal is extended. Therefore, as the area of the photodiode is increased, a conversion capability of the image sensor for converting the video signal to the electrical signal is enhanced.

Thus, a method of dividing a pixel array in one wafer into two wafers has been proposed.

FIG. 3 shows a pixel circuit in a pixel array having a three-dimensional structure.

Referring to FIG. 3, the pixel circuit includes a photodiode and a video signal conversion circuit for converting a video signal detected by the photodiode to an electrical signal. The video signal conversion circuit includes a transfer transistor Tx, a reset transistor Rx, a convert transistor Fx, and a select transistor Sx.

In the pixel array having the three-dimensional structure, the photodiode PD and the transfer transistor Tx are formed on the one wafer (left portion of a dotted line), and the remaining three transistors Rx, Fx, and Sx are formed on the other wafer (right portion of the dotted line). As described above, a video signal detected by the photodiode formed on the one wafer is transferred through the transfer transistor Tx to one terminal of the reset transistor Rx and to a gate terminal of the convert transistor Fx.

As described above, when the pixel circuit is divided and formed on the two wafers, there is a problem in that electric charges corresponding to the video signal detected from the one wafer need to be transferred to the other wafer without distortion.

In addition, as the area of the photodiode is relatively increased, the video signal to be incident to an adjacent photodiode may be erroneously incident to the photodiode, and the electric charges corresponding to the video signal detected by the adjacent photodiode may be erroneously introduced. Therefore, there is a problem in that signal crosstalk between the unit pixels needs to be prevented.

### SUMMARY OF THE INVENTION

The present invention provides a pixel array having a three-dimensional structure capable of preventing signal crosstalk between unit pixels and distortion of electric charges transferred from the one wafer to the other wafer.

The present invention also provides an image sensor including a pixel array having a three-dimensional structure capable of preventing signal crosstalk between unit pixels and distortion of charges transferred from one wafer to the other wafer.

According to an aspect of the present invention, there is provided a pixel array having a three-dimensional structure in which a photodiode, a transfer transistor, a reset transistor, a convert transistor, and a select transistor are divided and formed on a first wafer and a second wafer, and chips on the first and second wafers are connected in a vertical direction. The first wafer includes a plurality of photodiodes for generating electric charges corresponding to an incident video signal, a plurality of transfer transistors for transferring the electric charges generated by the photodiodes to floating diffusion regions, a plurality of STIs circling one of the photodiodes and one transfer transistor connected to the one photodiode, a first super-contact which extends from a lower portion of the plurality of the STIs to a lower surface of the wafer, and a second super-contact which penetrates the plurality of the STIs and a portion of the first super-contact. The electric charges accumulated in the floating diffusion regions are transferred to the second wafer through the second super-contact.

According to another aspect of the present invention, there is provided an image sensor comprising a pixel array, a plurality of color filters, and a plurality of micro lenses.

The pixel array has a three-dimensional structure in which a photodiode, a transfer transistor, a reset transistor, a convert transistor, and a select transistor are divided and formed on a first wafer and a second wafer, and chips on the first and second wafers are connected in a vertical direction after die-sorting the chips. The plurality of the color filters are formed on an upper portion of the pixel array. The plurality of the micro lenses are formed on an upper portion of the plurality of the color filters.

The first wafer includes a plurality of photodiodes for generating electric charges corresponding to an incident video signal, a plurality of transfer transistors for transferring the electric charges generated by the photodiodes to floating diffusion regions, a plurality of STIs circling one of the photodiodes and one transfer transistor connected to the one photodiode, a first super-contact which extends from a lower portion of the plurality of the STIs to a lower surface of the wafer, and a second super-contact which penetrates the plurality of the STIs and a portion of the first super-contact. The second wafer includes a plurality of the reset transistors converting the electric charges through the second super-contact to an electrical signal, a plurality of the convert transistors, and a plurality of the select transistors.

### BRIEF DESCRIPTION OF THE DRAWINGS

FIG. 1 is a view showing a planar structure of a conventional image sensor.

FIG. 2 is a view showing a conventional image sensor having a three-dimensional structure.

FIG. 3 is a view showing a pixel circuit in a pixel array having a three-dimensional structure.

FIG. 4 is a cross-sectional view showing a first wafer formed with a photodiode and a transfer transistor in a pixel array having a three-dimensional structure according to the present invention.

FIG. 5 is a cross-sectional view showing a second wafer formed with remaining elements except a photodiode and a transfer transistor in a pixel array having a three-dimensional structure according to the present invention.

FIG. 6 is a view showing a process of manufacturing an image sensor including a pixel array having a three-dimensional structure according to the present invention.

FIG. 7 is a plan view showing the photodiode, the transfer transistor, and the STI of FIG. 4.

FIG. 8 is a view showing a process of manufacturing the photodiode and the transfer transistor before generating a super-contact in FIG. 4.

FIG. 9 is a view showing a generated super-contact after the process of FIG. 8.

FIG. 10 is a view showing mechanism for preventing signal crosstalk between pixels in a pixel array according to the present invention.

FIG. 11 is a cross-sectional view showing an image sensor including a pixel array according to the present invention.

FIG. 12 is a view showing a pixel array having a three-dimensional structure according to another embodiment of the present invention.

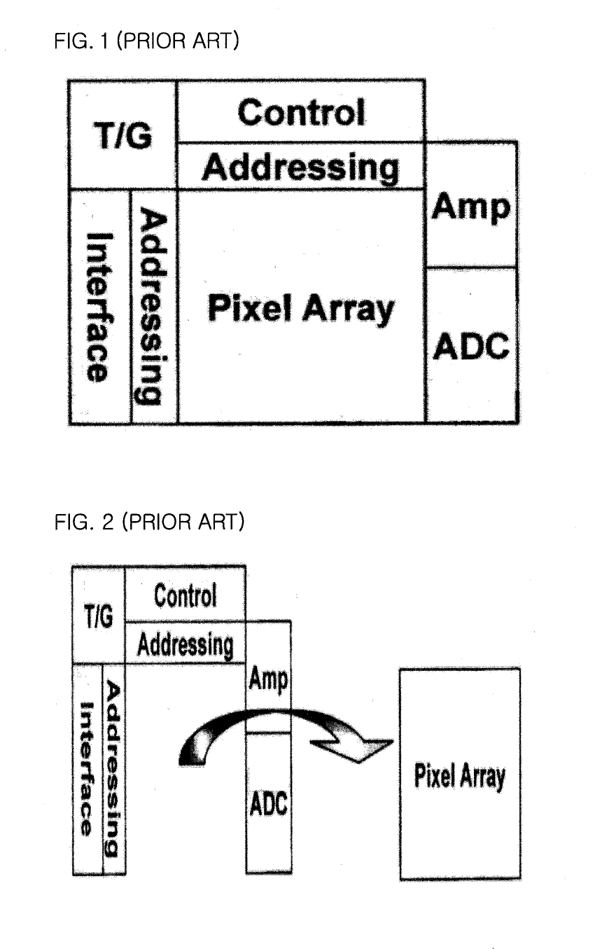

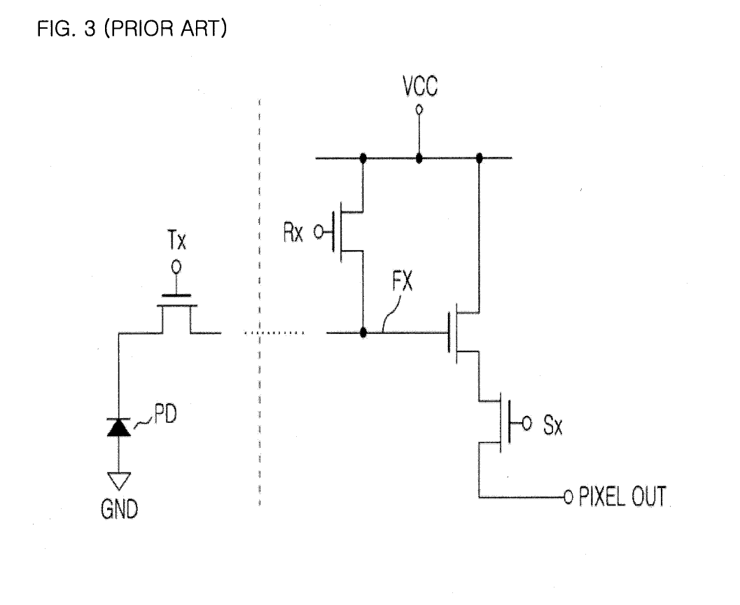

### DETAILED DESCRIPTION OF THE INVENTION

Hereinafter, embodiments according to the present invention will now be described in detail with reference to the accompanying drawings.

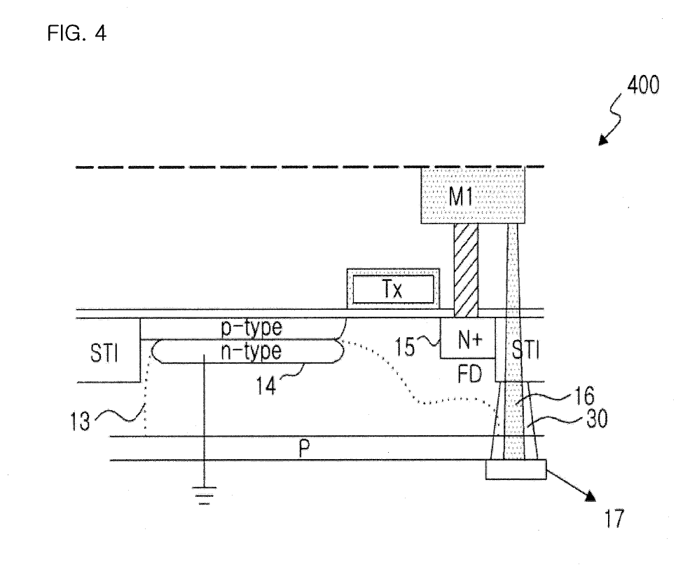

FIG. 4 shows a cross-section of a first wafer formed with a photodiode and a transfer transistor in a pixel array having a three-dimensional structure according to the present invention.

Referring to FIG. 4, the photodiode 14 and the transfer transistor Tx are formed in an area circled with a shallow trench insulator (STI). A first super-contact 30 is formed under the STI. The first super-contact 30 is formed so as to prevent signal crosstalk between unit pixels. Similar to the STI, the first super-contact 30 also circles the area where the photodiode 14 and the transfer transistor Tx are formed, it may be referred to as a first super-contact “circle” 30. The first super-contact 30 penetrates the STI down to a lower portion of the first wafer and is filled with an insulating material. In some cases, the first super-contact 30 may be filled with the same insulating material as the STI. A second contact 16 is formed in a region of the first super-contact 30. The second super-contact 16 serves as a charge transfer path for transferring electric charges accumulated in a floating diffusion region FD 15 to the second wafer through a metal line M1. The second super-contact, that is, the charge transfer path 16 penetrates down to a lower surface of the first wafer. In an end portion of the charge transfer path 16, a micro bumper 17 for absorbing a shock at the time of bonding the second wafer is formed. An N region of a PN diode shown in FIG. 4 is grounded.

The photodiode, the transfer transistor, the STI, and the super-contact shown in FIG. 4 will be described below in detail.

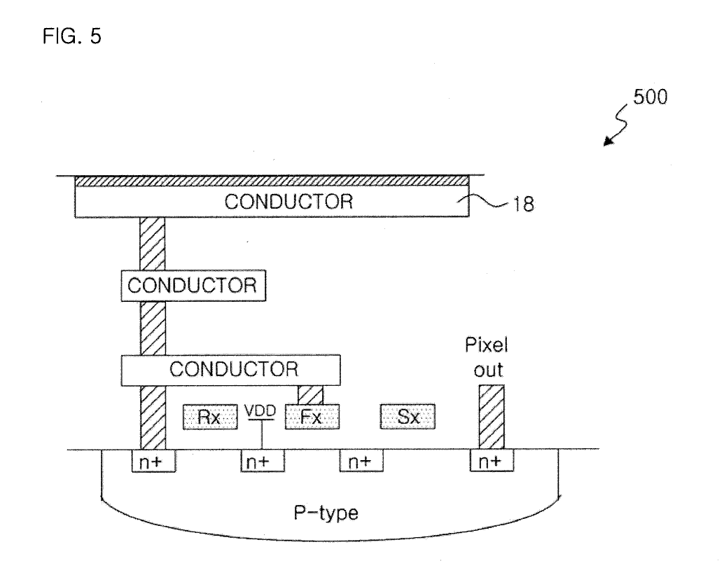

FIG. 5 is a cross-sectional view showing a second wafer formed with remaining elements except a photodiode and a transfer transistor in a pixel array having a three-dimensional structure according to the present invention.

Referring to FIG. 5, a reset transistor Rx, a convert transistor Fx, and a select transistor Sx are formed on the second wafer. A conductor 18 in an upper portion of FIG. 5 is bonded to the bumper 17 shown in FIG. 4. Therefore, the electric charges accumulated in the floating diffusion region 15 of the first wafer are transferred to one terminal of the reset transistor Rx and a gate terminal of the convert transistor Fx through the charge transfer path 16, the bumper 17, and the conductor 18.

Now, a process of manufacturing the two wafers shown in FIGS. 4 and 5 will be described. In general, an image sensor is formed by laminating color filters and micro lenses on an upper portion of a pixel array. Therefore, in order to form the image sensor, the pixel array is previously manufactured. Hereinafter, the methods of manufacturing the two wafers and the pixel array will be described together.

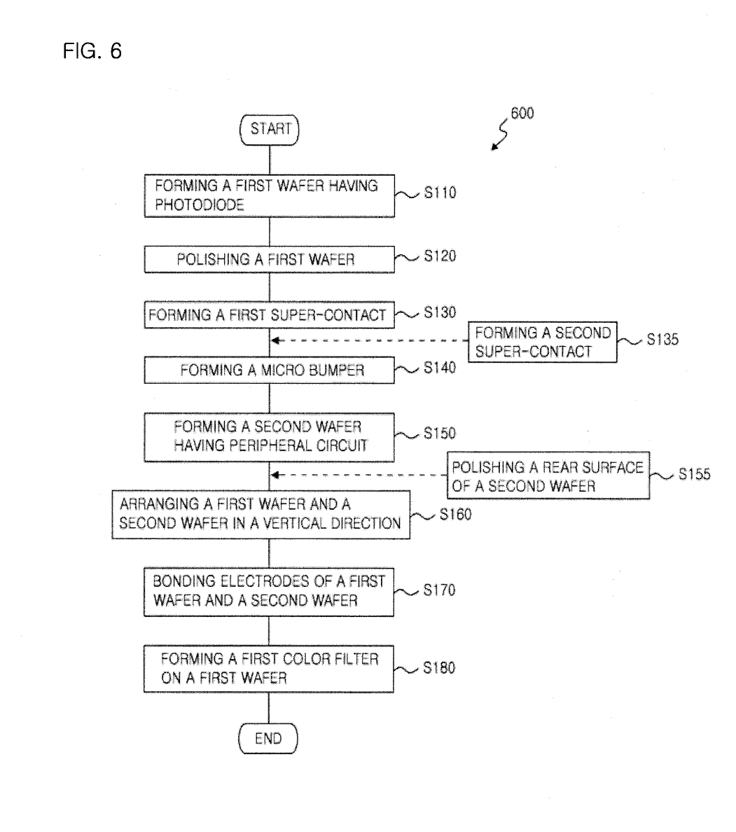

FIG. 6 is a view showing a process of manufacturing an image sensor including a pixel array having a three-dimensional structure according to the present invention.

Referring to FIG. 6, a process 600 of manufacturing the image sensor includes:

a step (S110) of forming a first wafer having a photodiode and a transfer transistor;

a step (S120) of polishing a rear surface of the first wafer;

a step (S130) of forming a first super-contact passing through the first wafer;

a step (S140) of forming a micro bumper on one surface of the first super-contact;

a step (S150) of forming a second wafer having remaining transistors except the photodiode and the transfer transistor of a pixel circuit;

a step (S160) of arranging wafers arranging the first and second wafers in a vertical direction;

a step (S170) of bonding wafers combining an electrode of the first wafer and an electrode of the second wafer corresponding to the electrode of the first wafer; and

a step (S180) of forming a color filter on the first wafer.

In some cases, a step (S135) of forming the second super-contact may be additionally performed between the step (S130) of forming the first super-contact and the step (S140) of forming the micro bumper. In addition, a step (S155) of polishing a rear surface of the second wafer may be additionally performed between the step (S150) of forming the second wafer and the step (S160) of arranging the wafers.

The above operations will be described in detail.

In the step (S110) of forming the first wafer S110, a photodiode 14, a transfer transistor Tx, a floating diffusion region FD, and a metal line M1 are formed on a front surface of the first wafer through the semiconductor process.

As a process applied to the first wafer, a specific process for enhance the dark property and the sensitivity of a sensor and for satisfying customer's requests may be applied.

In the step (S120) of polishing the rear surface of the first wafer, the rear surface of the first wafer is polished until a thickness of the first wafer has no more than 30 μm through a grinding process or a chemical mechanical polishing (CMP) process, and after that, the polished surface undergoes an etch process. According to specific use or situation, the step (S120) of polishing the rear surface of the first wafer may be performed with glass or the other silicon wafer attached to the front surface of the first wafer.

In the step (S120) of forming the first super-contact, a buried interconnection process or a super-contact process is basically performed to bond the wafer. The first super-contact is formed on the rear surface of the first wafer by a photolithography and a tungsten plug (W-PLUG) using an align key.

In some cases, in order to enhance the dark property of the image sensor, a nitride (SiN) film may be deposited or a double film with the SiN film and an oxide (SiO₂) film may be deposited on the rear surface of the first wafer after the step (S130) of forming the first super-contact, and after that, a second super-contact may be additionally formed around the photodiode through a CMP process (S135).

In the step (S140) of forming the micro bumper, through a micro bumper process, the micro bumper is formed on the surface of the first super-contact formed in the step (S130) of forming the first super-contact.

In the step (S150) of forming the second wafer, the reset transistor Rx, the convert transistor Fx, and the select transistor Sx are formed on the front surface of the second wafer through the semiconductor process. In some cases, a step (S155) of polishing a rear surface of the second wafer may be added.

In the step (S160) of arranging the wafer, the first and second wafers are arranged in the vertical direction, so that the micro bumper 17 on the first wafer and the conductor 18 on the second wafer are connected to each other. As a method of arranging the first and second wafers, a particular portion of the first wafer is penetrated through infrared ray transmission, etching, laser punching, and the like, and the first wafer and second wafers are optically up and down directions. Due to the infrared ray transmission, the wafers can be arranged without boring a hole. In the etching and the laser punching, the wafers can be arranged in a vertical direction by boring a hole and through optical pattern recognition.

In the step (S170) of bonding the wafers, the micro bumper 17 on the first wafer and the conductor 18 on the second wafer are bonded.

In the step (S180) of forming the color filters, the color filters and the micro lenses are sequentially laminated on the first wafer.

In the step (S110) of forming the first wafer, 0.18 μm or 90 nm process technology can be applied on the wafer epitaxially grown through an epitaxial method. In the step (S150) of forming the second wafer, 0.25 μm or 0.35 μm process technology can be applied on the wafer.

The specific process according to the present invention is the process for the first super-contact and the second super-contact. Now, uses of the first super-contact and the second super-contact will be described.

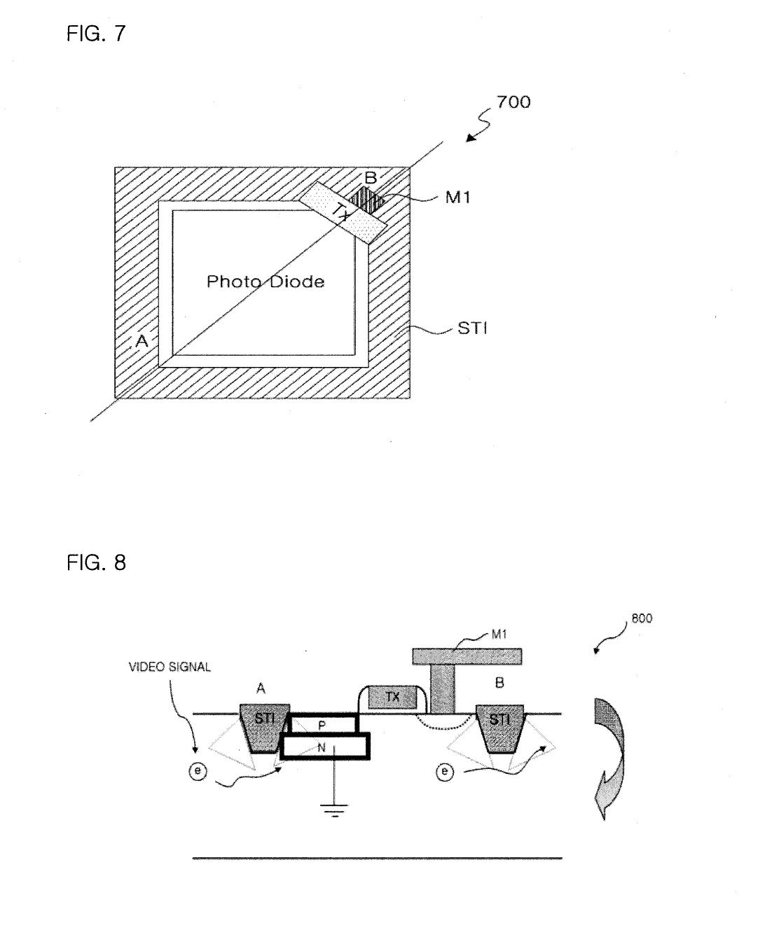

FIG. 7 is a plan view showing the photodiode, the transfer transistor, and the STI of FIG. 4.

Referring to FIG. 7, the transfer transistor Tx is formed on one edge of the rectangular photodiode, and the metal line M1 is formed on an upper portion of the floating diffusion region (FD, not shown). The photodiode and the transfer transistor are circled with the STI. Although the STI circles all sides of a unit pixel in FIG. 7, a partial or whole portion of surfaces may be opened.

FIG. 8 is a view showing a process of manufacturing the photodiode and the transfer transistor before generating a super-contact in FIG. 4.

FIG. 8 shows a cross-sectional view of the photodiode and the transfer transistor taken along a line A-B of FIG. 7. In FIG. 8, the super-contact is not yet formed on the STI. Referring to FIG. 8, electric charges generated corresponding to the video signal from an arbitrary unit pixel circled with the STI may be transferred over the STI to an adjacent unit pixel. In this case, signal crosstalk between unit pixels occurs. In order to prevent the signal crosstalk between unit pixels, the present invention provides the first super-contact. An N region of a PN diode is grounded.

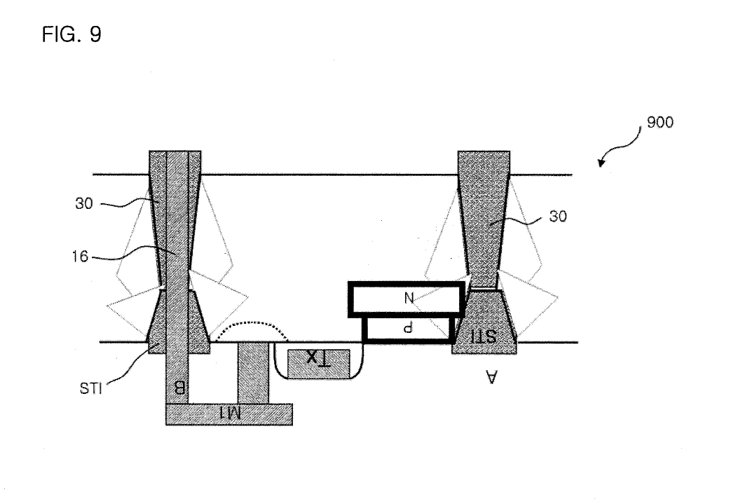

FIG. 9 is a view showing a generated super-contact after the process of FIG. 8.

The first super-contact 30 is formed to extend to an end of the wafer under the STI of FIG. 8. In FIG. 9, the lower and upper portions of the wafer of FIG. 8 are faced up and down. The second super-contact 16 is formed on a predetermined portion of the first super-contact, that is, a portion overlapped with the metal M1 formed on an upper portion of the floating diffusion region. The second super-contact 16 is filled with the same conductor as the metal M1 or another conductor. The second super-contact 16 is used as the charge transfer path 16.

Conventionally, since a via-contact formed on a partial region of a photodiode is used as the charge transfer path 16, it causes a decrease in the area of the photodiode. However, in the pixel array according to the present invention, since the charge transfer path 16 is formed on a partial region of the first super-contact, the area of the photodiode can be relatively increased. Therefore, it can be understood that a dark property of an image sensor using the pixel array having an increasing area of the photodiode will be enhanced.

Referring to FIG. 9, a region where the second super-contact 16 is formed is denoted by B, which is in the vicinity of the floating diffusion region adjacent to the transfer transistor Tx as shown in FIG. 8.

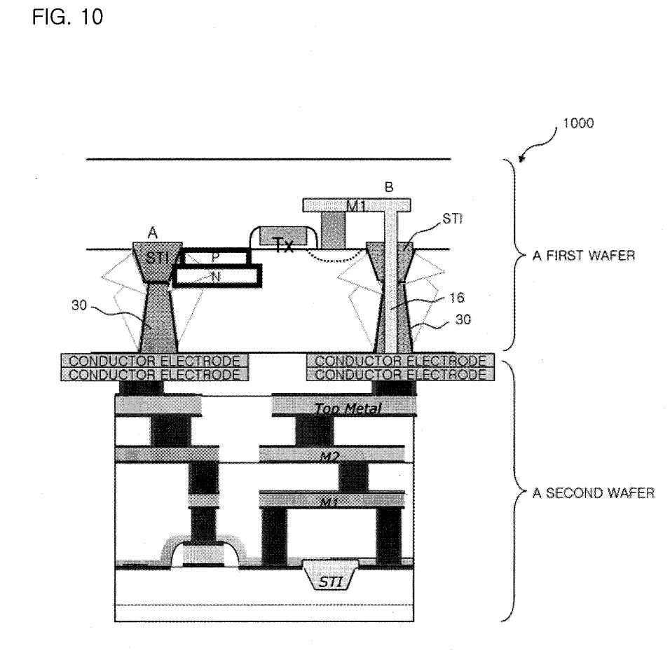

FIG. 10 is a cross-sectional view showing a pixel array according to the present invention.

Referring to FIG. 10, the pixel array can be formed by laminating a chip obtained by sorting the first wafer formed with the photodiodes and the transfer transistors on an upper portion of another chip obtained by sorting the second wafer formed with the other transistors except for the transfer transistors among the video signal conversion circuits. The two chips are connected with each other through a conductive electrode.

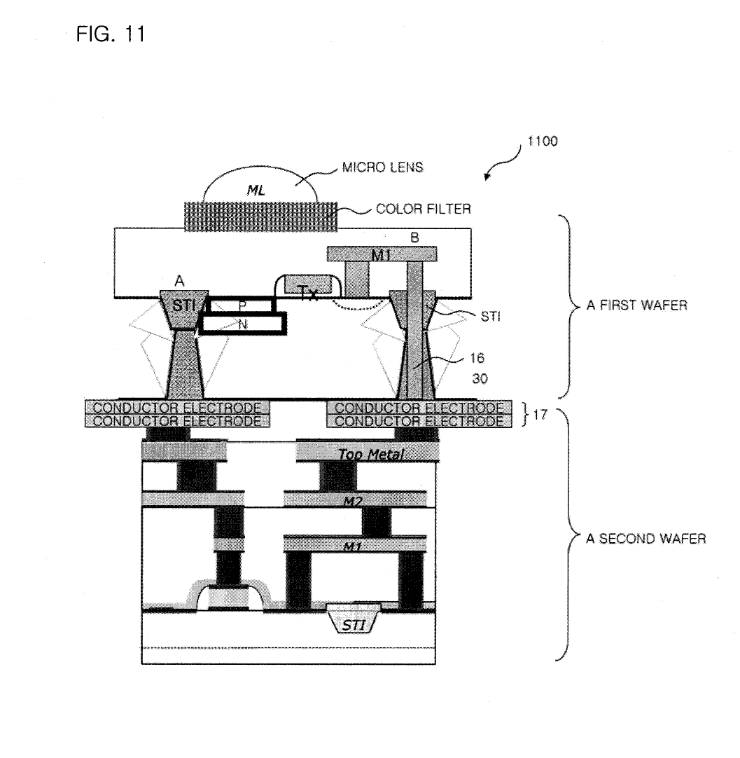

FIG. 11 is a cross-sectional view showing an image sensor including a pixel array according to the present invention.

Referring to FIG. 11, the image sensor according to the present invention is formed by laminating the color filters and the micro lenses on the upper portion of the chip obtained by die-sorting the upper portion of the pixel array, that is, the first wafer according to the present invention shown in FIG. 10.

The above description is made on the unit photodiode and the transfer transistor formed on the first wafer and the reset transistor, the convert transistor, and the select transistor formed on the second wafer. However, the pixel array and the image sensor having the three-dimensional structure according to the present invention can be applied to a structure where the reset transistor, the convert transistor, and the select transistor formed on the second wafer are designed to share at least two photodiodes and the corresponding two transfer transistors formed on the first wafer.

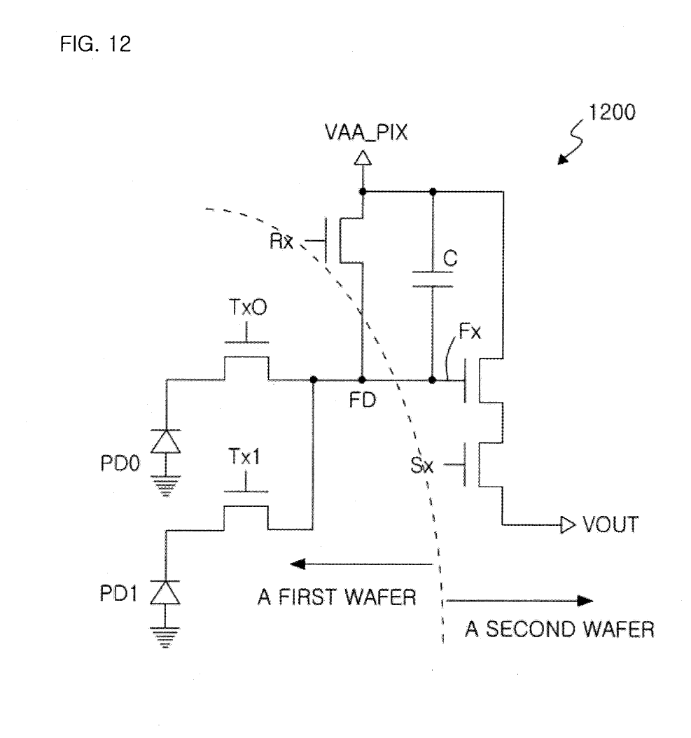

FIG. 12 is a view showing a pixel array having a three-dimensional structure according to another embodiment of the present invention.

Referring to FIG. 12, two photodiodes PD0 and PD1 and two transfer transistors Tx0 and Tx1 connected to the corresponding two photodiodes which are formed on the first wafer are designed to share one reset transistor Rx, one convert transistor, and one select transistor Sx formed on the second wafer.

In this case, since the number of transistors to be formed on the second wafer is reduced, the second wafer can be added with other function blocks.

What is claimed is:

1. A pixel array having a three-dimensional structure in which a photodiode, a transfer transistor, a reset transistor, a convert transistor, and a select transistor are divided and formed on a first wafer and a second wafer, and chips on the first and second wafers are connected in a vertical direction,
wherein the first wafer comprises:
a plurality of photodiodes for generating electric charges corresponding to an incident video signal;
a plurality of transfer transistors for transferring the electric charges generated by the photodiodes to floating diffusion regions;
a plurality of shallow trench insulators (STIs) for circling one of the photodiodes and one transfer transistor connected to the one photodiode;
a first super-contact which extends from a lower portion of the plurality of the STIs to a lower surface of the first wafer; and
a second super-contact which penetrates the plurality of the STIs and a portion of the first super-contact, and
wherein the electric charges accumulated in the floating diffusion regions are transferred to the second wafer through the second super-contact.

2. The pixel array according to claim 1, wherein the first super-contact is filled with an insulating material.

3. The pixel array according to claim 2, wherein the insulating material has the same material with that of the STI.

4. The pixel array according to claim 2, wherein the insulating material is an SiN film or a double film laminated with an SiN film and an SiO₂ film.

5. The pixel array according to claim 1, wherein the second super-contact is filled with a conductive material.

6. The pixel array according to claim 5, wherein the conductive material has the same material with that of the metal line formed on the floating diffusion regions.

7. An image sensor comprising:
a pixel array having a three-dimensional structure in which a photodiode, a transfer transistor, a reset transistor, a convert transistor, and a select transistor are divided and formed on a first wafer and a second wafer, chips on the first and second wafers are connected in a vertical direction after die-sorting the chips;
a plurality of color filters formed on the pixel array; and
a plurality of micro lenses formed on an upper portion of the plurality of color filters,
wherein the first wafer comprises:
a plurality of photodiodes for generating electric charges corresponding to an incident video signal;
a plurality of transfer transistors for transferring the electric charges generated by the photodiodes to floating diffusion regions;
a plurality of STIs circling one of the photodiodes and one transfer transistor connected to the one photodiode;
a first super-contact which extends from a lower portion of the plurality of the STIs to a lower surface of the first wafer; and
a second super-contact which penetrates the plurality of the STIs and a portion of the first super-contact, and
wherein the second wafer comprises:
a plurality of the reset transistors converting the electric charges through the second super-contact to an electrical signal;
a plurality of the convert transistors; and
a plurality of the select transistors.
